(19) United States
(12) Patent Application Publication
(10) Pub. No.: US 2025/0306647 A1
(43) Pub. Date: Oct. 2, 2025

(54) CONNECTION DEVICE AND ELECTRONIC APPARATUS

(71) Applicant: Lenovo (Beijing) Limited, Beijing (CN)

(72) Inventors: Yingce ZHENG, Beijing (CN); Detao YOU, Beijing (CN)

(21) Appl. No.: 19/078,943

(22) Filed: Mar. 13, 2025

(30) Foreign Application Priority Data
Mar. 30, 2024 (CN) 202410384280.4

(51) Int. Cl. G06F 1/16

(52) U.S. Cl. CPC G06F 1/1681

(57) ABSTRACT

A connection device includes: a first connection component, configured to connect a first body; a second connection component, configured to connect a second body; and an adjustment component, configured to connect the first connection component and the second connection component, and to enable rotation of the first connection component with respect to the second connection component, where during a first rotation process, the first connection component and the second connection component rotate synchronously through the adjustment component, and where during a second rotation process, the adjustment component is controlled to enable rotation for one of the first connection component and the second connection component.

### RELATED APPLICATION(S)

This application claims priority to Chinese Patent Application No. 2024103842804 filed on Mar. 30, 2024, which is incorporated herein by reference in its entirety.

### FIELD OF THE TECHNOLOGY

The present disclosure relates to the field of electronic device, and in particular to a connection device and an electronic apparatus.

### BACKGROUND

Electronic devices such as laptop computers and foldable mobile phones have a first body and a second body that may be opened and closed, and the first body and the second body are connected by a connection device to achieve the functions of unfolding and closing. Some electronic devices may achieve 360-degree flipping, but when the electronic device is in the closed state, the free ends of the first body and the second body are flush, while in the unfolded state, there is a step difference between the free ends of the first body and the second body. The step difference means that the two free ends are not flush, which affects user experience.

### SUMMARY

The present disclosure in certain embodiments provides a connection device and an electronic apparatus.

In one aspect, the present disclosure provides a connection device. The connection device includes: a first connection component, configured to connect a first body; a second connection component, configured to connect a second body; and an adjustment component, configured to connect the first connection component and the second connection component, and to enable rotation of the first connection component with respect to the second connection component, where during a first rotation process, the first connection component and the second connection component rotate synchronously through the adjustment component, and where during a second rotation process, the adjustment component is controlled to enable rotation for one of the first connection component and the second connection component.

In certain embodiments, the adjustment component includes: a first linkage member, configured to connect the first connection component and rotate synchronously with the first connection component; a second linkage member, configured to connect the second connection component and rotate synchronously with the second connection component, where the second linkage member includes a first connection portion and a second connection portion, the first connection portion being used for transmission connection with the first linkage member during the first rotation process, and the second connection portion being used for transmission separation between the first linkage member and the second linkage member during the second rotation process; and a control member, configured to limit the rotation of the first linkage member during the second rotation process.

In certain embodiments, the control member includes: a first control member, configured to connect the first connection component and being arranged coaxially with the first linkage member; a second control member, configured to connect the second connection component and being arranged coaxially with the second linkage member; and a sliding member, arranged between the first control member and the second control member, and used for switching between the first connection component and the second connection component, so that one of the first connection component and the second connection component enables rotation during the second rotation process.

In certain embodiments, the first control member is a first wheel body, the second control member is a second wheel body, the sliding member is a slider, and the slider has a first end and a second end, during the first rotation process, the first end of the slider is in sliding cooperation with the first wheel body, and the second end of the slider is in sliding cooperation with the second wheel body, and during the second rotation process, the first end of the slider is connected with the first wheel body to limit the rotation of the first wheel body, and the second end of the slider is in sliding cooperation with the second wheel body.

In certain embodiments, a side wall of an outer periphery of the first wheel body includes an arc-shaped curved surface and a concave surface concave relative to the arc-shaped curved surface, a side wall of an outer periphery of the second wheel body includes a first arc surface and a second arc surface, and a radius of the first arc surface is smaller than a radius of the second arc surface, where during the first rotation process, the first end of the slider slides with the arc-shaped curved surface of the first wheel body, and the second end of the slider slides with the first arc surface, and where during the second rotation process, the second arc surface abuts and slides with the second end of the slider, and the first end of the slider abuts with the concave surface of the first wheel body to limit the rotation of the first wheel body.

In certain embodiments, an outer side wall of the first wheel body is formed with a first limiting structure and a second limiting structure, the first limiting structure is in a strip shape and extends along a circumference of the first wheel body, and the second limiting structure is in a strip shape and extends along an axial direction of the first wheel body, where an outer side wall of the second wheel body is formed with a third limiting structure and a fourth limiting structure, the third limiting structure is in a strip shape and extends along a circumference of the second wheel body, and the fourth limiting structure is in a spiral shape, where in the first rotation process, the first end of the slider slides with the first limiting structure of the first wheel body, and the second end of the slider slides with the third limiting structure of the second wheel body, and where in the second rotation process, the first end of the slider slides with the second limiting structure of the first wheel body, and the second end of the slider slides with the fourth limiting structure of the second wheel body.

In certain embodiments, the first linkage member is a first gear, and the second linkage member is a second gear, the second gear includes an annular side wall, and the first connection portion is a plurality of gear teeth arranged on the annular side wall and is in transmission connection to the first gear, the second connection portion is an avoidance surface formed by a surface of the annular side wall where no gear teeth are arranged, and the first linkage member and the second linkage member have opposite rotation directions.

In a second aspect, the present disclosure provides an electronic apparatus. The electronic apparatus includes: a first body, a second body, and a connection device, where the connection device includes: a first connection component, configured to connect a first body; a second connection component, configured to connect a second body; and an adjustment component, configured to connect the first connection component and the second connection component, and to enable rotation of the first connection component with respect to the second connection component, where during a first rotation process, the first connection component and the second connection component rotate synchronously through the adjustment component, and where during a second rotation process, the adjustment component is controlled to enable rotation for one of the first connection component and the second connection component.

In certain embodiments, the first body is in a first position and a second position relative to the second body, and a free end of the first body is flush with a free end of the second body, and wherein a size of the first body along a first direction is smaller than a size of the second body along the first direction, and the first direction is perpendicular to a rotation direction of the first connection component.

In certain embodiments, the first body has a display surface for display and a first surface facing away from the display surface, and the second body has an input surface for input and a second surface facing away from the input surface, where in a first position, the display surface is arranged opposite to the input surface, and in a projection along a second direction, a connection line formed by a connection end of the first body and a connection end of the second body has a first tilt angle relative to the first body,
where in a second position, the first surface is arranged opposite to the second surface, and in a projection along the second direction, the connection line formed by the connection end of the first body and the connection end of the second body has a second tilt angle relative to the first body, and where, the second direction is parallel to a rotation direction of the first connection component, and the first tilt angle is equal to the second tilt angle.

### BRIEF DESCRIPTION OF THE DRAWINGS

Contents, purposes, features, and advantages of the present disclosure become clearer through the following description of certain embodiments of the present disclosure with reference to the accompanying drawings, in which:

FIG. 1 is a schematic structural diagram of a connection device according to certain embodiments of the present disclosure;

FIG. 2A is a schematic structural diagram of a connection device in a closed state according to certain embodiments of the present disclosure;

FIG. 2B is a schematic structural diagram of a connection device when unfolded to a predetermined angle according to certain embodiments of the present disclosure;

FIG. 2C is a schematic structural diagram of a connection device when unfolded to a maximum angle according to certain embodiments of the present disclosure;

FIG. 3A is a schematic structural diagram of a first linkage member and a second linkage member when a connection device is in a closed state according to certain embodiments of the present disclosure;

FIG. 3B is a schematic structural diagram of a first linkage member and a second linkage member when a connection device is unfolded to a predetermined angle according to certain embodiments of the present disclosure;

FIG. 3C is a schematic structural diagram of the cooperation between a first linkage member and a second linkage member when a connection device is unfolded to a maximum angle according to certain embodiments of the present disclosure;

FIG. 4 is a schematic exploded diagram of a connection device according to certain embodiments of the present disclosure;

FIG. 5 is a schematic structural diagram of a connection device according to certain embodiments of the present disclosure;

FIG. 6A is a schematic structural diagram of the cooperation between a first control member and a second control member when a connection device is in a closed state according to certain embodiments of the present disclosure;

FIG. 6B is a schematic structural diagram of the cooperation between a first control member and a second control member when a connection device is unfolded at a predetermined angle according to certain embodiments of the present disclosure;

FIG. 6C is a schematic structural diagram of the cooperation between a first control member and a second control member when a connection device is unfolded at a maximum angle according to certain embodiments of the present disclosure;

FIG. 7 is a schematic exploded diagram of a connection device according to certain embodiments of the present disclosure;

FIG. 8 is a schematic structural diagram of a connection device according to certain embodiments of the present disclosure;

FIG. 9A is a schematic structural diagram of a first control member cooperating with a second control member when a connection device is in a closed state according to certain embodiments of the present disclosure;

FIG. 9B is a schematic structural diagram of a first control member cooperating with a second control member when a connection device is unfolded to a predetermined angle according to certain embodiments of the present disclosure;

FIG. 9C is a schematic structural diagram of a first control member cooperating with a second control member when a connection device is unfolded to a maximum angle according to certain embodiments of the present disclosure;

FIG. 10A is a schematic structural diagram of an electronic apparatus in a closed state according to certain embodiments of the present disclosure; and

FIG. 10B is a schematic structural diagram of an electronic apparatus at a maximum unfolded angle according to certain embodiments of the present disclosure.

The reference numerals in the accompanying drawings are as follows:
First connection component 100, first rotation shaft 110, first rotation shaft connection portion 120;
Second connection component 200, second rotation shaft 210, second rotation shaft connection portion 220;
Adjustment component 300, first linkage member 310, second linkage member 320, gear teeth 321, avoidance surface 322, control member 330, first wheel body 331, arc-shaped curved surface 3311, concave surface 3312, first limiting structure 3313, second limiting structure 3314, second wheel body 332, first arc surface 3321, second arc surface 3322, third limiting structure 3323, fourth limiting structure 3324, slider 333;
Transmission gear 400;
Mounting bracket 500, first bracket 510, second bracket 520, third bracket 530, fourth bracket 540;
First body 600;
Second body 700.

### DETAILED DESCRIPTION

Certain embodiments of the present disclosure are described with reference to the accompanying drawings. The descriptions are exemplary and are not to limit the scope of the present disclosure. In the following detailed description, for ease of explanation, many details are set forth to provide a comprehensive understanding of certain embodiments of the present disclosure. One or more embodiments may be implemented without the described details. Descriptions of certain known structures and technologies are omitted to avoid unnecessary confusion to the concepts of the present disclosure.

The terms used herein are for describing certain embodiments and are not to limit the present disclosure. The terms “comprise”, “include”, or the like used herein indicate the existence of the features, steps, operations and/or components, but do not exclude the existence or addition of one or more other features, steps, operations or components.

Terms (including technical and scientific terms) used herein have the meanings commonly understood in the technical field unless otherwise defined. The terms used herein should be interpreted as having a meaning consistent with the context of the present disclosure and should not be interpreted in an idealized or overly rigid manner.

When using expressions such as “at least one of A, B, and C, or the like”, the expressions are interpreted according to the meaning of the expression commonly understood in the technical field (for example, “a system having at least one of A, B, and C” should include but is not limited to a system having A alone, B alone, C alone, A and B, A and C, B and C, and/or A, B, C, or the like).

Electronic apparatus such as laptop computers and foldable phones include a first body, a second body, and a connection device. The connection device may include two connection members. The first body and the second body are each connected to a connection component. The first body and the second body are unfolded and closed by relative rotation of the two connection components.

Due to the modeling parameters, the plane formed by the axes of the two connection components may have an inclination angle relative to the first body, so that the plane is in a non-perpendicular state with the first body. When the electronic apparatus is in a closed state, the free end of the first body and the free end of the second body are generally flush. The modeling parameters may lead to the size of the first body and the size of the second body being unequal in the first direction perpendicular to the rotation direction.

The relative rotation between the first body and the second body may be achieved through a synchronous transmission connection device. With a synchronous transmission connection device, the first body and the second body have the same unfolding angle. For example, if the first body rotates 180 degrees in the forward direction, the second body will rotate 180 degrees in the reverse direction, so that the electronic apparatus unfolds 360 degrees. However, since the sizes of the first body and the second body are not equal, when the electronic apparatus is in the unfolded state, there is a step difference between the first body and the second body. The step difference is manifested as: the free end of the first body is not flush with the free end of the second body, and there is some distance between the two free ends in the first direction. The step difference will affect the user experience.

The relative rotation between the first body and the second body may be achieved by an asynchronous transmission connection device. The asynchronous transmission connection device is adopted, and the connection device includes a first connection component and a second connection component. The process of the first body and the second body unfolding from the minimum angle to the maximum angle includes three stages. The first stage is to control the rotation of the first connection component alone, the second stage is to control the rotation of the second connection component alone, and the third stage is to control the rotation of the first connection component alone. However, the asynchronous transmission connection device may have the following features.

When the unfolding angle of the first body and the second body is a predetermined switching angle, a switch from the first stage to the second stage may occur, and the predetermined switching angle is, for example, 120 degrees. Taking the electronic apparatus as a laptop computer as an example, under normal use, the unfolding angle of the first body and the second body is approximately between 100 degrees and 130 degrees, and this angle range is called the normal use angle. Since the normal use angle is relatively close to the predetermined switching angle, under normal use, a switch may occur during the process of opening the electronic apparatus, and the switch may cause a sense of frustration, affecting the feel of opening.

Certain electronic apparatus has touch screens. For the asynchronous transmission connection device, one connection component may remain fixed in each stage, and the other connection component may rotate under the action of external force, which is equivalent to using one connection component to support the display screen. The supporting force of the display screen is relatively small. Therefore, when the user operates the touch screen, the display screen may shake and the stability is poor.

Certain embodiments of the present disclosure provide a connection device and an electronic apparatus having the connection device. Compared with a synchronous transmission connection device, the connection device provided by certain embodiments of the present disclosure help reduce or eliminate the step difference, thereby improving the user experience. In certain embodiments, the connection device helps alleviate the frustration when the electronic apparatus is operated under normal use, thereby improving the feel of use. In certain embodiments, within the normal use angle range, the connection device helps support the first body and the second body, thereby improving stability.

The technical solution provided by the present disclosure is described with reference to the accompanying drawings.

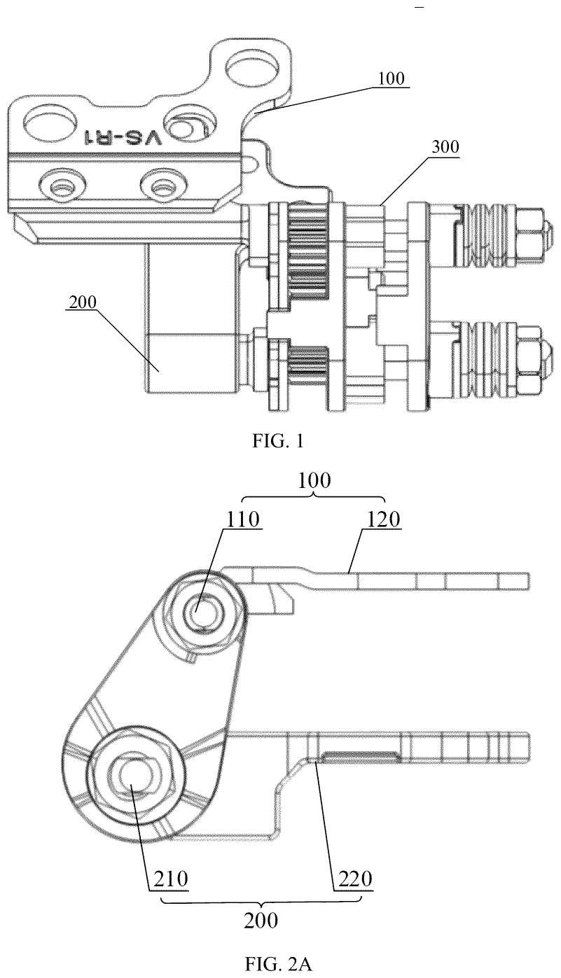

With reference to FIG. 1, the present disclosure in certain embodiments provides a connection device, which may be applied to electronic apparatus, such as laptop computers, mobile phones, or the like. The electronic apparatus may include a first body 600 and a second body 700 that may be opened and closed. Taking the electronic apparatus as a laptop computer as an example, one of the first body 600 and the second body 700 may be a display terminal with a display screen, and the other may be a system terminal with a keyboard. The connection device may include: a first connection component 100, a second connection component 200, and an adjustment component 300.

The first connection component 100 is used to connect the first body 600. For example, the first connection component 100 may include a first rotation shaft 110 and a first rotation shaft connection portion 120. The first rotation shaft connection portion 120 may be sleeved and supported on the outer periphery of the first rotation shaft 110. The first rotation shaft connection portion 120 may be fixedly connected to the first body 600 by a mechanical structure such as bolts, so that the first body 600 and the first connection component 100 rotate synchronously.

The second connection component 200 is used to connect the second body 700. For example, the second connection component 200 may include a second rotation shaft 210 and a second rotation shaft connection portion 220. The second rotation shaft connection portion 220 may be sleeved and supported on the outer periphery of the second rotation shaft 210. The second rotation shaft connection portion 220 may be fixedly connected to the second body 700 by a mechanical structure such as bolts, so that the second body 700 and the second connection component 200 rotate synchronously.

The adjustment component 300 is connected to the first connection component 100 and the second connection component 200, and is used to provide the first connection component 100 with respect to the second connection component 200. The relative rotation of the first connection component 100 and the second connection component 200 includes two processes, namely the first rotation process and the second rotation process.

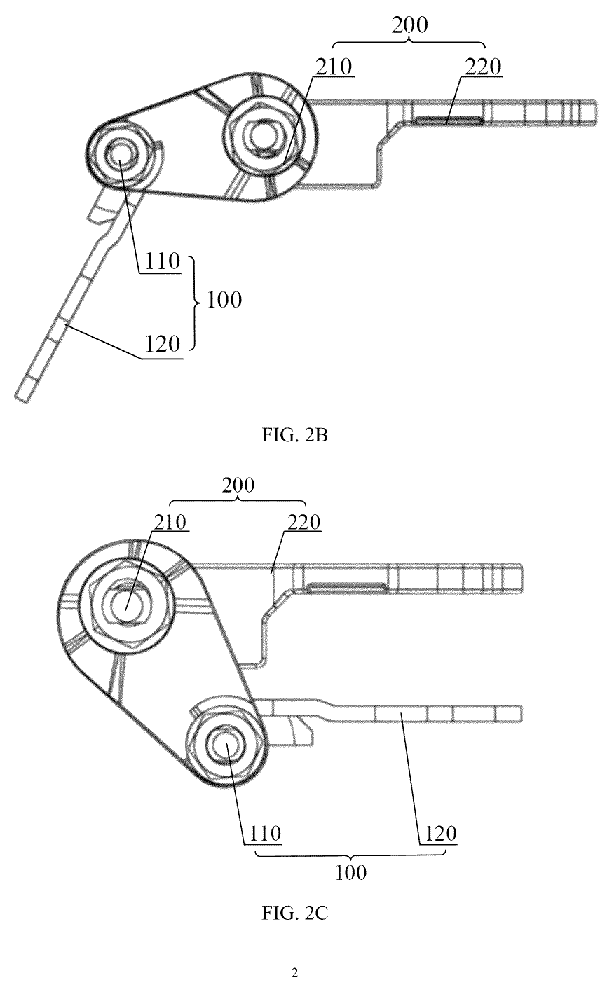

Taking the electronic apparatus as a laptop computer as an example, the screen end and the system end of the laptop computer may be opened and closed between a minimum angle and a maximum angle, the minimum angle may be 0 degrees, and the maximum angle may be 360 degrees. The first rotation process may represent a flip between the minimum angle and the predetermined angle, for example, the first rotation process represents a rotation from the state shown in FIG. 2A to the state shown in FIG. 2B. The second rotation process may represent a flip between a predetermined angle and a maximum angle, for example, the first rotation process represents a rotation from the state shown in FIG. 2B to the state shown in FIG. 2C. The predetermined angle may be 260 degrees or other angles, which are not limited in the present disclosure. The second rotation process may also represent a flip between the minimum angle and the first predetermined angle, and the first rotation process may represent a flip between the first predetermined angle and the maximum angle.

In the first rotation process, the first connection component 100 and the second connection component 200 rotate synchronously through the adjustment component 300. Synchronous rotation may be achieved through structures such as gears and synchronous belts, and the present disclosure does not limit the method for achieving synchronous rotation.

In the second rotation process, the adjustment component 300 is controlled to facilitate rotation of one of the first connection component 100 and the second connection component 200, that is, in the second rotation process, the adjustment component 300 separates the transmission between the first connection component 100 and the second connection component 200, so that one connection component remains fixed and the other connection component may rotate relative to a transmission assembly. In the second rotation process, the first connection component 100 and the second connection component 200 rotate asynchronously.

According to certain embodiments of the present disclosure, the adjustment component 300 may make the first connection component 100 and the second connection component 200 rotate synchronously in the first rotation process and rotate asynchronously in the second rotation process, that is, the connection device adopts a hybrid mode of synchronous and asynchronous rotation.

Since asynchronous transmission may be performed, when the first body 600 and the second body 700 are unfolded from the minimum angle to the maximum angle, the rotation angle of the first connection component 100 is not equal to the rotation angle of the second connection component 200. The difference between the two rotation angles may be used to compensate for the step difference between the free end of the first body 600 and the free end of the second body 700, thereby improving the user experience.

In certain embodiments, synchronous transmission may be performed first, and then asynchronous transmission. By configuring the angle at which the first rotation process and the second rotation process are switched, the predetermined switching angle is configured within the angle range of abnormal use, so that the rotation process does not switch when the first body 600 and the second body 700 are unfolded to the normal use angle. Therefore, under normal use, the switching of the rotation shaft does not occur during the opening process, thereby alleviating the sense of frustration and improving the feel of use. In addition, since synchronous transmission may be performed, the first transmission component and the second transmission component may be used to support the body during the synchronous transmission process, and the supporting force may be sufficiently large, to avoid large shaking when user operates the display screen, thereby improving stability.

In certain embodiments, the connection device may include a first connection component 100, a second connection component 200, and an adjustment component 300, where the adjustment component 300 may include a first linkage member 310, a second linkage member 320, and a control member 330.

The first linkage member 310 and the first connection component 100 may be fixedly connected via a mechanical structure, and the first linkage member 310 and the first connection component 100 may rotate synchronously.

The second linkage member 320 and the second connection component 200 may be fixedly connected through a mechanical structure, and the second linkage member 320 and the second connection component 200 may rotate synchronously. In addition, the second linkage member 320 includes a first connection portion and a second connection portion.

The control component 330 is used to limit the rotation of the first linkage member 310 during the second rotation process. The control member 330 and the first linkage member 310 may be connected to each other by a mechanical structure, for example, one of the control member 330 and the first linkage member 310 has a groove, and the other has a protrusion, and the groove and the protrusion are engaged to achieve the limit.

During the first rotation process, the first connection portion of the second linkage member 320 is in transmission connection with the first linkage member 310, and the first linkage member 310 and the second linkage member 320 may rotate synchronously. The first linkage member 310 drives the first connection component 100 to rotate, and the first connection component 100 drives the first body 600 to rotate; the second linkage member 320 drives the second connection component 200 to rotate, and the second connection component 200 drives the second body 700 to rotate, so that the first body 600 and the second body 700 may rotate synchronously, and the opening and closing may be realized.

During the second rotation process, the second connection portion of the second linkage member 320 separates the transmission between the first linkage member 310 and the second linkage member 320. When the second connection component 200 is regarded as stationary, the second body 700 becomes or maintains stationary. The first linkage member 310 drives the first connection component 100 to rotate, and the first connection component 100 drives the first body 600 to rotate, thereby realizing asynchronous rotation of the first body 600 and the second body 700.

In certain embodiments, the first linkage member 310 and the second linkage member 320 may realize transmission connection and transmission separation, and during the transmission separation process, the control member 330 is used to limit the rotation of the first linkage member 310 around its own axis to achieve the locking of the first linkage member 310. The first connection component 100 may be locked, so that the first body 600 connected to the first connection component 100 maintains an unchanged expansion angle, so that the expansion angle between the first body 600 and the second body 700 is at a maximum angle at the conclusion of the second rotation process.

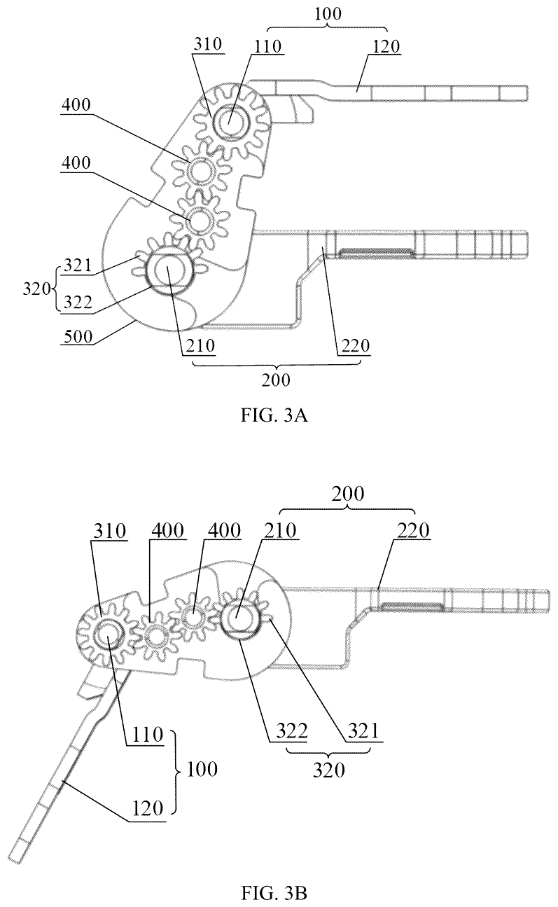

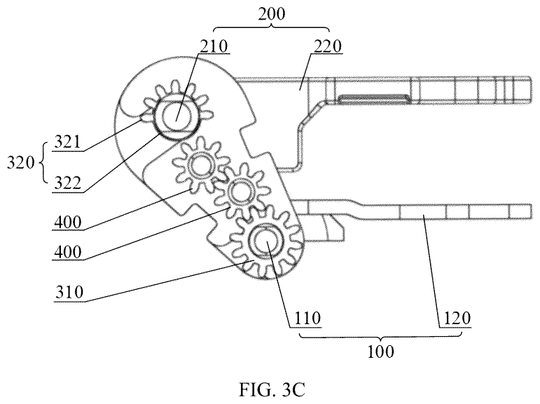

In view of FIG. 3A to FIG. 3C, and in certain embodiments, the connection device may include a first connection component 100, a second connection component 200, and an adjustment component 300, where the adjustment component 300 may include a first linkage member 310, a second linkage member 320, and a control member 330.

The first linkage member 310 is a first gear. Accordingly, the first connection component 100 may include a first rotation shaft 110. The first gear may be sleeved and supported on the outer periphery of the first rotation shaft 110. The first gear and the first rotation shaft 110 may be an integral structural member or may be fixed by a mechanical structure.

The second linkage member 320 is a second gear. Accordingly, the second connection component 200 may include a second rotation shaft 210. The second gear may be sleeved and supported on the outer periphery of the second rotation shaft 210. The second gear and the second rotation shaft 210 may be an integral structural member or may be kept fixed by a mechanical structure. In certain particular embodiments, the second gear is a half-teeth gear, the second gear includes an annular side wall, and a portion of the circumferential surface of the annular side wall is provided with gear teeth 321, and the gear teeth 321 on the surface of the annular side wall are the first connection portion mentioned herein elsewhere. Another portion of the circumferential surface of the annular side wall is not provided with gear teeth 321 to form an avoidance surface 322, and the avoidance surface 322 is the second connection portion mentioned herein elsewhere.

In certain embodiments, the gear teeth of the first gear are transmission connected to the gear teeth 321 of the second gear. When the rotation direction of the first gear and the second gear is the same, the first body 600 and the second body 700 rotate in the same direction, which makes it impossible to achieve normal opening and closing of the electronic apparatus. Therefore, in certain embodiments, the rotation directions of the first gear and the second gear are opposite, so that the meshing transmission of the first gear and the second gear drives the first rotation shaft 110 in the first connection component 100 and the second rotation shaft 210 in the second connection component 200 to rotate in the opposite direction, and then drive the first body 600 and the second body 700 to move closer to or away from each other through the first connection component 100 and the second connection component 200, thereby realizing the opening and closing of the electronic apparatus.

In certain embodiments, the first linkage member 310 adopts a first gear, and the second linkage member 320 adopts a second gear with a half-tooth structure. The transmission connection between the first linkage member 310 and the second linkage member 320 is realized by the gear teeth 321 of the second gear, and the transmission separation between the first linkage member 310 and the second linkage member 320 is realized by the avoidance surface 322 of the second gear. The first linkage member 310 and the second linkage member 320 may together realize synchronous transmission, with desirable transmission accuracy, and the switching angle between the first rotation process and the second rotation process may be controlled with enhanced precision.

In certain embodiments, the transmission connection between the first gear and the second gear may be achieved in a variety of ways. In one example, during the first rotation process, the gear teeth 321 on the annular side wall surface may directly mesh with the first gear for transmission. During the second rotation process, the avoidance surface 322 may avoid the gear teeth of the first gear, thereby separating the transmission between the first gear and the second gear. In another example, during the first rotation process, the gear teeth 321 on the annular side wall surface may mesh with the first gear through a transmission assembly, and the transmission assembly may include a transmission gear 400. In the second rotation process, the avoidance surface 322 may avoid the gear teeth of the transmission gear 400, so that the transmission between the first gear and the second gear is separated. Compared with the direct meshing of the first gear and the second gear, the transmission gear 400 in certain embodiments is arranged between the first gear and the second gear to increase the distance between the first connection component 100 and the second connection component 200, providing a larger installation space for the control member 330, thereby facilitating assembly. In certain embodiments, when only one transmission gear 400 is provided between the first gear and the second gear, the first gear and the second gear will rotate in the same direction. Therefore, the number of transmission gears 400 may be an even number, for example, the number of transmission gears 400 is 2 or 4, to ensure that the first gear and the second gear rotate in opposite directions, thereby ensuring the normal opening and closing of the first body 600 and the second body 700.

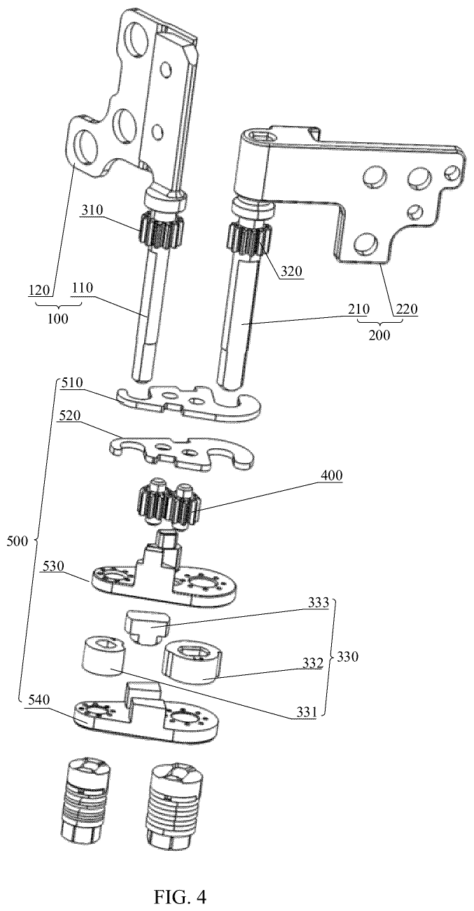

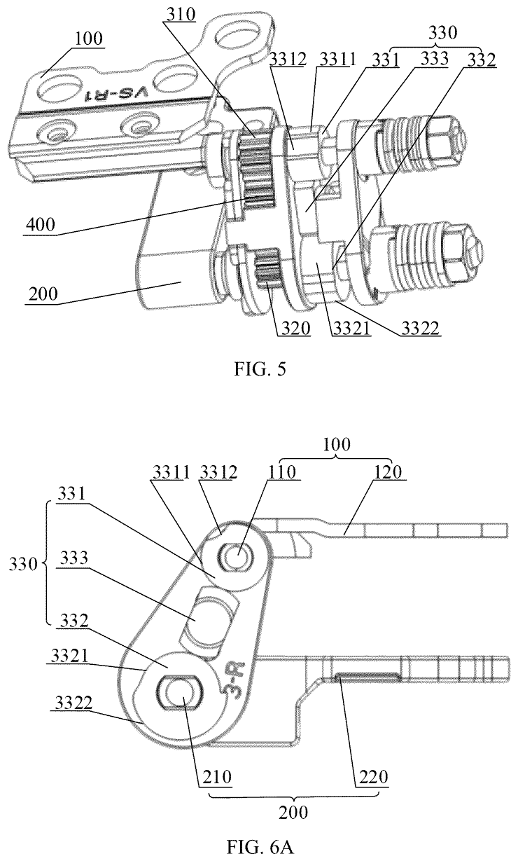

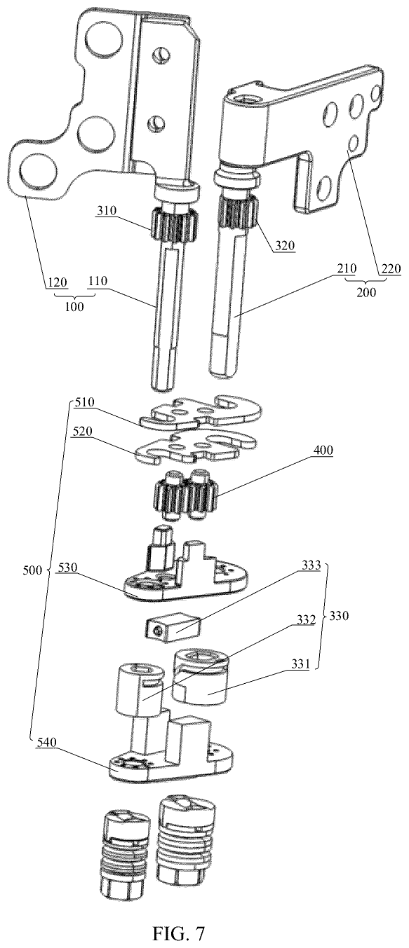

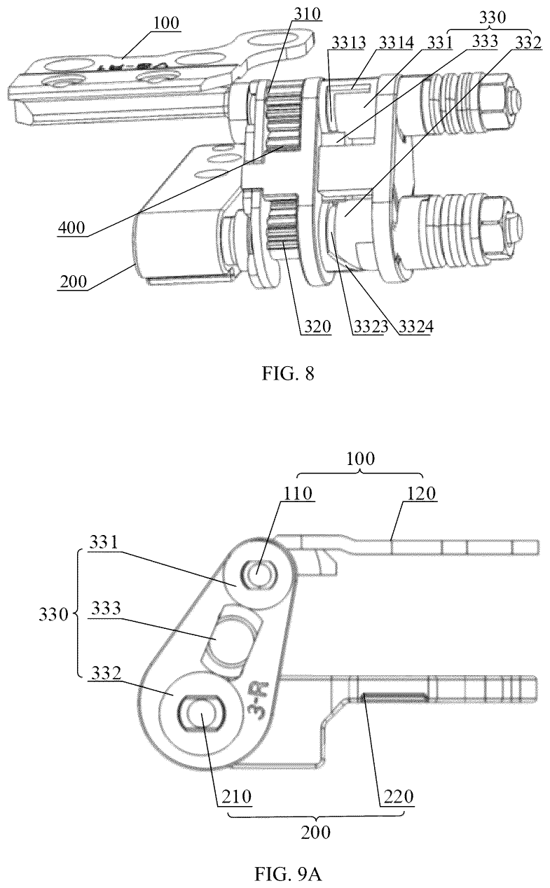

Reference is made to FIG. 4, FIG. 5, FIG. 7, and FIG. 8. In certain embodiments, the connection device may include a first connection component 100, a second connection component 200, and an adjustment component 300, where the adjustment component 300 may include a first linkage member 310, a second linkage member 320 and a control member 330, and the control member 330 may include: a first control member, a second control member, and a sliding member.

The first control member is connected to the first connection component 100 and is coaxially arranged with the first linkage member 310. For example, the first control member may adopt a wheel body, a gear or the like in structure, and the first control member and the first linkage member 310 may be coaxially aligned with the first connection component 100, respectively, to form the coaxial arrangement.

The second control member is connected to the second connection component 200 and is coaxially arranged with the second linkage member 320. For example, the first control member may adopt a wheel body, a gear or the like in structure, and the second control member and the second linkage member 320 may be coaxially aligned with the first connection component 100, to form the coaxial arrangement.

The sliding member is disposed between the first control member and the second control member, and is used for switching between the first connection component 100 and the second connection component 200, so that one of the first connection component 100 and the second connection component 200 provides rotation during the second rotation process. For example, the sliding member may lock one of the first control member and the second control member by sliding in a predetermined direction, and allow the other to continue to rotate freely, where the predetermined direction may be a direction parallel to the rotation axis of the first connection component 100, or other directions.

In certain embodiments, the control member 330 includes a first control member, a second control member, and a sliding member, and the first control member and the second control member are respectively arranged coaxially with the first connection component 100 and the second connection component 200, and the switching of the rotation process is achieved by controlling the sliding member.

In certain embodiments, a mounting bracket 500 may be employed for assisting the assembly of various components and members. For example, the mounting bracket 500 may include a first bracket 510, a second bracket 520, a third bracket 530, and a fourth bracket 540. The present disclosure is not limited to any particular structure of the mounting bracket 500.

For example, some of the mounting brackets 500 may be simultaneously sleeved on the outer peripheries of the first rotation shaft 110 in the first connection component 100 and the second rotation shaft 210 in the second connection component 200. The mounting bracket 500 is mainly used for supporting and limiting various components. For example, the transmission gear 400 may be arranged between the second bracket 520 and the third bracket 530, so that the second bracket 520 and the third bracket 530 may engage with the end surface of the transmission gear 400, thereby limiting the axial position of the transmission gear 400. The first control member, the second control member, and the sliding member may be arranged between the third bracket 530 and the fourth bracket 540, so that the third bracket 530 and the fourth bracket 540 may axially limit the first control member and the second control member, and may limit the sliding direction of the sliding member.

Reference is made to FIG. 4, FIG. 5, FIG. 7, and FIG. 8. In certain embodiments, the first control member is a first wheel body 331, and the first wheel body 331 is coaxially arranged with the first linkage member 310. For example, the first connection component 100 includes a first rotation shaft 110, and the first linkage member 310 may be a first gear sleeved on the outer periphery of the first rotation shaft 110, or the first linkage member 310 may also adopt other structures. The first wheel body 331 may be sleeved on the outer periphery of the first rotation shaft 110.

In certain embodiments, the second control member is a second wheel body 332, and the second wheel body 332 is coaxially arranged with the second linkage member 320. For example, the second connection component 200 includes a second rotation shaft, and the second linkage member 320 may be a second gear sleeved on the outer periphery of the second rotation shaft, or the second linkage member 320 may also adopt other structures. The second wheel body 332 may be sleeved on the outer periphery of the second wheel rotation shaft.

In certain embodiments, the sliding member is a slider 333, and the slider 333 has a first end and a second end.

During the first rotation process, and in certain embodiments, the first end of the slider 333 slides with the first wheel body 331, and the second end of the slider 333 slides with the second wheel body 332, without constraining the transmission between the first linkage member 310 and the second linkage member 320.

During the second rotation process, and in certain embodiments, the first end of the slider 333 is connected to the first wheel body 331 in a limited position. The limited position connection may be abutment, for example, the first end of the slider 333 abuts against the surface of the first wheel body 331 and remains relatively still or stationary. The limited position connection may also be a sliding connection, for example, the slider 333 may slide relative to the first wheel body 331 in one direction (for example, the axial direction of the first wheel body 331), but remains still or stationary relative to the first wheel body 331 in another direction (for example, the circumferential direction of the first wheel body 331). The rotation of the first wheel body 331 is limited by the limited position connection. The second end of the slider 333 is slidably engaged with the second wheel body 332.

In certain embodiments, a mounting bracket 500 may be employed for assisting the assembly of various components and members. For example, the mounting bracket 500 may include a first bracket 510, a second bracket 520, a third bracket 530 and a fourth bracket 540. The present disclosure may employ any suitable structure of the mounting bracket 500.

For example, some of the mounting brackets 500 may be simultaneously sleeved on the outer peripheries of the first rotation shaft 110 in the first connection component 100 and the second rotation shaft 210 of the second connection component 200. The mounting bracket 500 is mainly used to support and limit the positions of various components. For example, the transmission gear 400 may be arranged between the second bracket 520 and the third bracket 530, so that the second bracket 520 and the third bracket 530 may engage with the end surface of the transmission gear 400, thereby limiting the axial position of the transmission gear 400. The first control member, the second control member, and the sliding member may be arranged between the third bracket 530 and the fourth bracket 540, so that the third bracket 530 and the fourth bracket 540 may axially limit the first control member and the second control member, and may also limit the sliding direction of the sliding member.

In certain embodiments, both the first control member and the second control member adopt a wheel body structure, and synchronous rotation, asynchronous rotation and switching of the rotation process are achieved through the rotation of the wheel body and the cooperation of the slider 333.

The connection device in certain embodiments is described herein in relation to FIG. 4 to FIG. 7C.

The connection device in certain embodiments includes a first connection component 100, a second connection component 200 and an adjustment component 300. The adjustment component 300 may include a first linkage member 310, a second linkage member 320 and a control member 330. The control member 330 may include: a first control member, a second control component, and a sliding member. Descriptions of the structures of these components may be found herein elsewhere and are not repeated in favor of brevity. In certain embodiments, the first control member is the first wheel body 331, the second control member is the second wheel body 332, and the sliding member is the slider 333. The first wheel body 331, the second wheel body 332 and the slider 333 are described herein in conjunction with FIG. 4 and FIG. 5.

In certain embodiments, the first wheel body 331 is a concave wheel. The side wall of the outer periphery of the first wheel body 331 includes an arc-shaped curved surface 3311 and a concave surface 3312. The concave surface 3312 is concave relative to the arc-shaped curved surface 3311.

In certain embodiments, the second wheel body 332 is a cam, and the side wall of the outer periphery of the second wheel body 332 includes a first arc surface 3321 and a second arc surface 3322, and the radius of the first arc surface 3321 is smaller than the radius of the second arc surface 3322. The side wall of the outer periphery of the second wheel body 332 may include a transition surface, which is located between the first arc surface 3321 and the second arc surface 3322, to smoothly transition the radius difference between the first arc surface 3321 and the second arc surface 3322.

In certain embodiments, the first end of the slider 333 adopts a convex arc structure, to facilitate engagement with the concave surface 3312 of the first wheel body 331, and the second end of the slider 333 may adopt a flat surface or a curved surface structure.

In certain embodiments, the first body 600 and the second body 700 of the electronic apparatus may be opened and closed between a minimum angle and a maximum angle, the minimum angle may be 0 degrees, and the maximum angle may be 360 degrees, where the first rotation process may represent the rotation between the minimum angle and the predetermined angle, and the second rotation process may represent the rotation between the predetermined angle and the maximum angle. In view of FIG. 4 to FIG. 6C, the unfolding process of the electronic apparatus is described by taking the predetermined angle of 260 degrees as an example. The predetermined angle may be any suitable angle other than an angle of 260 degrees.

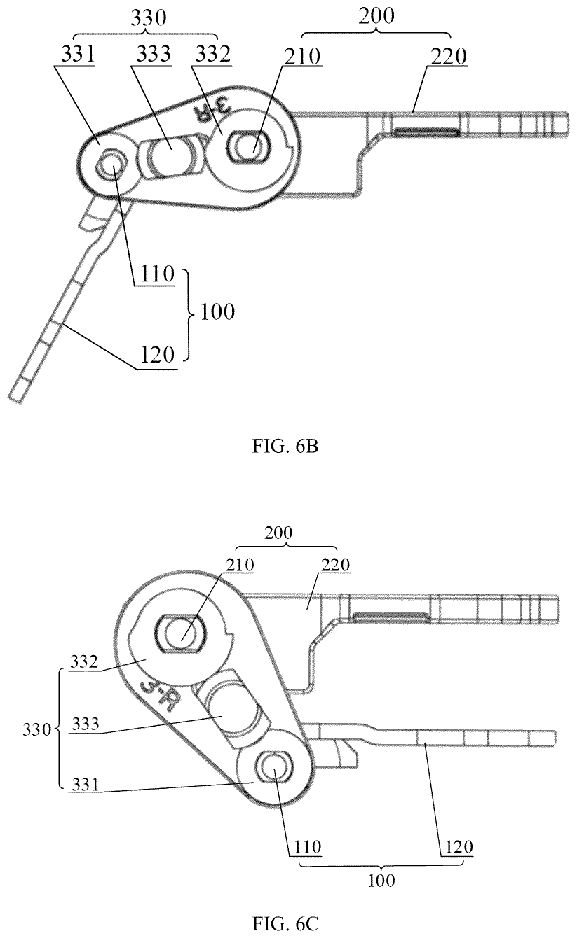

Reference is made to FIG. 4, FIG. 5, and FIG. 6A. During the process of the electronic apparatus unfolding from 0 degrees to 260 degrees (for example, the first rotation process), the first linkage member 310 and the second linkage member 320 are synchronously transmitted. Description of the method of synchronous transmission may be found herein elsewhere. For example, the transmission is carried out by meshing the teeth of the first gear and the teeth of the second gear. The first gear and the second gear respectively rotate 130 degrees, thereby driving the first connection component 100 and the second connection component 200 to rotate 130 degrees respectively, so that the first body 600 and the second body 700 are unfolded 260 degrees. In certain embodiments, the first end of the slider 333 is slidably engaged with the arc-shaped curved surface 3311 of the concave wheel of the first wheel body 331, and the second end of the slider 333 is slidably engaged with the first arc surface 3321 of the second wheel body 332, and the slider 333 does not exert a restraining effect on the first wheel body 331 and the second wheel body 332.

Reference is made to FIG. 4, FIG. 5, and FIG. 6B. When the electronic apparatus is unfolded to 260 degrees, transmission separation occurs between the first linkage member 310 and the second linkage member 320. Description of the method of transmission separation may be found herein elsewhere. For example, as the second gear rotates, the avoidance surface 322 on the second gear rotates to the meshing position of the second gear and other components (such as the transmission gear 400), and the gear teeth of the second gear disengage from the transmission gear 400, so that the transmission between the first gear and the second gear is separated. In certain embodiments, the second end of the slider 333 slides to the terminal area of the first arc surface 3321 of the second wheel body 332, and the transition surface or the starting area of the first arc surface 3321 pushes the slider 333 to move toward the first wheel body 331 until the first end of the slider 333 is engaged with the concave surface 3312 of the first wheel body 331, thereby limiting the rotation of the first rotation shaft 110, but the second end of the slider 333 may still slide around the second arc surface 3322 of the second wheel body 332, and the first rotation process is switched to the second rotation process.

Reference is made of FIG. 4, FIG. 5, and FIG. 6C. During the process of the electronic apparatus being unfolded from 260 degrees to 360 degrees (for example, the second rotation process), the transmission separation is maintained between the first linkage member 310 and the second linkage member 320. For example, the avoidance surface 322 on the second gear is separated from the gear teeth of other components, so that the rotation of other components may not be transmitted to the second linkage member. In certain embodiments, the first end of the slider 333 abuts against the concave surface 3312 of the first wheel body 331 to limit the rotation of the first wheel body 331, thereby limiting the rotation of the first connection component 100. In certain embodiments, the second arc surface 3322 of the second wheel body 332 abuts against and slides with the second end of the slider 333. In the second rotation process, the slider 333, the first wheel body 331, and the first connection component 100 remain relatively still or stationary, where the second connection component 200 rotates around its own axis, and the second connection component 200 may continue to rotate 100 degrees.

Certain features of the unfolding process of the electronic apparatus from 0 degrees to 360 degrees have been described. The closing process of the electronic apparatus from 360 degrees to 0 degrees may be opposite to or a reversal of the unfolding process, and the description of the closing process is not repeated in favor of brevity.

In certain embodiments, the synchronous transmission and asynchronous transmission of the first connection component 100 and the second connection component 200 are realized, and the switching between the synchronous transmission and the asynchronous transmission is realized through the cooperation of the concave wheel, the convex wheel or the cam, and the slider 333.

Through the above unfolding process, and in certain embodiments, the first body 600 rotates 130 degrees under the drive of the first connection component 100, and the second body 700 rotates 230 degrees under the drive of the second connection component 200. The rotation angles of the first body 600 and the second body 700 are not equal. The angle difference is used to compensate for the step difference between the free end of the first body 600 and the free end of the second body 700, thereby improving the user experience.

In certain embodiments, the unfolding process first performs synchronous transmission and then asynchronous transmission, and the switching angle between synchronous transmission and asynchronous transmission is 260 degrees. Taking the electronic apparatus as a laptop computer as an example, the unfolding angle of the electronic apparatus normally used by the user is approximately between 100 degrees and 130 degrees. Therefore, when the first body 600 and the second body 700 are unfolded to the normal use angle, the switching between synchronous transmission and asynchronous transmission does not occur, thereby alleviating the sense of frustration and improving the feel of use. In addition, the process of unfolding the first body 600 and the second body 700 to the normal usage angle is a synchronous transmission process. During the synchronous transmission process, the first transmission assembly and the second transmission assembly may be used to simultaneously support the first body 600, and the supporting force is relatively large. When the user operates the first body 600, large shaking is reduced or avoided, thereby improving stability.

The connection device in certain embodiments is described in view of FIG. 7 to FIG. 9C.

In certain embodiments, the connection device includes a first connection component 100, a second connection component 200 and an adjustment component 300. The adjustment component 300 may include a first linkage member 310, a second linkage member 320 and a control member 330. The control member 330 may include: a first control member, a second control member and a sliding member. Structural description of these components may be found herein elsewhere, and is not repeated in favor of brevity. In certain particular embodiments, the first control member is a first wheel body 331, the second control member is a second wheel body 332, and the sliding member is a slider 333. Description of the first wheel body 331, the second wheel body 332, and the slider 333 may be found in relation to FIG. 7 and FIG. 8.

In certain embodiments, the outer wall of the first wheel body 331 is formed with a first limiting structure 3313 and a second limiting structure 3314. The first limiting structure 3313 is strip-shaped and extends along the circumference of the first wheel body 331. The second limiting structure 3314 is strip-shaped and extends along the axial direction of the first wheel body 331. In certain particular embodiments, respective ends of the first limiting structure 3313 and the second limiting structure 3314 are connected to form an L-shaped structure.

In certain embodiments, the outer side wall of the second wheel body 332 is formed with a third limiting structure 3323 and a fourth limiting structure 3324. The third limiting structure 3323 is strip-shaped and extends along the circumference of the second wheel body 332, and the third limiting structure 3323 corresponds to the position of the first limiting structure 3313. The fourth limiting structure 3324 is spiral-shaped, and the respective ends of the third limiting structure 3323 and the fourth limiting structure 3324 are connected.

The end of the slider 333 may be provided with a structure that matches the first wheel body 331 and the second wheel body 332. In certain embodiments, when the first limiting structure 3313, the second limiting structure 3314, the third limiting structure 3323 and the fourth limiting structure 3324 are all groove structures, then a protrusion structure may be provided at the end of the slider 333. In certain embodiments, when the above four limiting structures are all protrusion structures, then a groove structure may be provided at the end of the slider 333.

In certain embodiments, and further in view of FIG. 7 to FIG. 9C, the unfolding process of the electronic apparatus is described by taking the first rotation process as a rotation between 0 degrees and 260 degrees and the second rotation process as a rotation between 260 degrees and 360 degrees as an example.

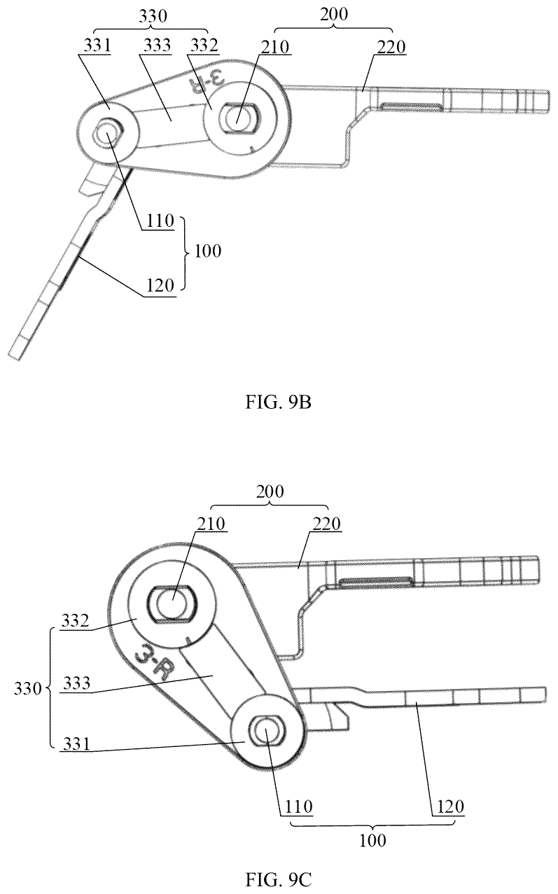

Reference is made to FIG. 7, FIG. 8, and FIG. 9A. During the process of the electronic apparatus unfolding from 0 degrees to 260 degrees (for example, the first rotation process), the first linkage member 310 and the second linkage member 320 are synchronously transmitted. The method of synchronous transmission may be found described herein elsewhere. For example, transmission is performed by meshing the teeth of the first gear and the teeth of the second gear. The first gear and the second gear respectively rotate 130 degrees, thereby driving the first connection component 100 and the second connection component 200 to rotate 130 degrees respectively, so that the first body 600 and the second body 700 are unfolded 260 degrees. In certain particular embodiments, the first end of the slider 333 is slidably engaged with the first limiting structure 3313 of the first wheel body 331, and the second end of the slider 333 is slidably engaged with the third limiting structure 3323 of the second wheel body 332. In certain embodiments, when the slider 333 is regarded as a stationary part, the first wheel body 331 and the second wheel body 332 rotate around their own axes respectively, and the slider 333 does not affect the synchronous transmission between the first connection component 100 and the second connection component 200, such that the first connection component 100 and the second connection component 200 rotate synchronously.

Reference is made to FIG. 7, FIG. 8, and FIG. 9B. In certain embodiments, when the electronic apparatus is unfolded to 260 degrees, transmission separation occurs between the first linkage member 310 and the second linkage member 320. Description of the transmission separation method may be found herein elsewhere. For example, as the second gear rotates, the avoidance surface 322 on the second gear rotates to the meshing position of the second gear and other components (such as the transmission gear 400). Then the first end of the slider 333 slides to the connection area of the first limiting structure 3313 and the second limiting structure 3314, the second end of the slider 333 slides to the connection area of the third limiting structure 3323 and the fourth limiting structure 3324, the first rotation process switches to the second rotation process.

Reference is made to FIG. 7, FIG. 8, and FIG. 9C. During the process of the electronic apparatus being unfolded from 260 degrees to 360 degrees (for example, the second rotation process), the transmission separation is maintained between the first linkage member 310 and the second linkage member 320. For example, the avoidance surface 322 on the second gear is separated from the gear teeth of other components (such as the transmission gear 400), so that the rotation of other components is not transmitted to the second linkage. In certain embodiments, the first end of the slider 333 slides with the second limiting structure 3314 of the first wheel body 331, and the second end of the slider 333 slides with the fourth limiting structure 3324 of the second wheel body 332. The fourth limiting structure 3324 exerts a force on the second end of the slider 333, causing the slider 333 to slide in a direction parallel to the axis of the first wheel body 331. When the slider 333 slides, the first end of the slider 333 cooperates with the second limiting structure 3314 and limits the first wheel body 331 from rotating around its own axis. During the second rotation process, the first wheel body 331 and the first connection component 100 remain relatively still or stationary. When the first wheel body 331 and the first connection component 100 are regarded as stationary, the second connection component 200 rotates around its own axis, so that the second connection component 200 may continue to rotate 100 degrees, and the slider 333 slides in a direction parallel to the axis of the first wheel body 331.

Certain features of the unfolding process of the electronic apparatus from 0 degrees to 360 degrees have been described. The closing process of the electronic apparatus from 360 degrees to 0 degrees may be opposite to or a reversal of the unfolding process, and the description of the closing process is not repeated in favor of brevity.

In certain embodiments, the synchronous transmission and asynchronous transmission of the first connection component 100 and the second connection component 200 are realized, and the switching between the synchronous transmission and the asynchronous transmission is realized through the cooperation of the groove wheel structure and the slider 333.

Through the above unfolding process, and in certain embodiments, the first body 600 rotates 130 degrees under the drive of the first connection component 100, and the second body 700 rotates 230 degrees under the drive of the second connection component 200. The rotation angles of the first body 600 and the second body 700 are not equal. The angle difference is used to compensate for the step difference between the free end of the first body 600 and the free end of the second body 700, thereby improving the user experience.

In certain embodiments, the unfolding process first performs synchronous transmission and then asynchronous transmission, and the switching angle between synchronous transmission and asynchronous transmission is approximately 260 degrees. Taking the electronic apparatus as a laptop computer as an example, the unfolding angle of the electronic apparatus normally used by the user is approximately between 100 degrees and 130 degrees. When the first body 600 and the second body 700 are unfolded to the normal use angle, the switching between synchronous transmission and asynchronous transmission does not occur, thereby alleviating the sense of frustration and improving the feel of use. The process of unfolding the first body 600 and the second body 700 to the normal usage angle is a synchronous transmission process. During the synchronous transmission process, the first transmission assembly and the second transmission assembly may be used to simultaneously support the first body 600, and the supporting force is relatively large. When the user operates the first body 600, large shaking is reduced or avoided, thereby improving stability.

The present disclosure also provides an electronic apparatus, which may be a laptop computer, a foldable mobile phone, or the like. The electronic apparatus may include a first body 600 and a second body 700 that may be opened and closed. Taking the electronic apparatus as a laptop computer as an example, one of the first body 600 and the second body 700 may be a display terminal having a display screen, and the other may be a system terminal having a keyboard. The electronic apparatus also includes a connection device, which may be any of the connection devices described herein elsewhere.

In certain embodiments, the connection device includes a first connection component 100, a second connection component 200, and an adjustment component 300, where the first connection component 100 is connected to the first body 600, the second connection component 200 is connected to the second body 700, and the adjustment component 300 is connected to the first connection component 100 and the second connection component 200, and the adjustment component 300 is used to facilitate rotation between the first connection component 100 and the second connection component 200. When the first body 600 is in a first rotation mode relative to the second body 700, and during the first rotation process of the connection device, the first connection component 100 and the second connection component 200 rotate synchronously through the adjustment component 300. When the first body 600 is in a second rotation mode relative to the second body 700, and during the second rotation process, the connection device is controlled by the adjustment component 300 to allow rotation of one of the first connection component 100 and the second connection component 200.

The electronic apparatus provided according to certain embodiments helps alleviate the step difference problem, thereby improving the user experience. In addition, the frustration associated with opening the electronic apparatus under normal use may be alleviated, the feel of use may be improved, and the stability of the first body 600 and the second body 700 may be improved.

In certain embodiments, the first body 600 and the second body 700 are rectangular, and the direction perpendicular to the rotation direction of the first connection component 100 is called the first direction. The size of the first body 600 along the first direction is smaller than the size of the second body 700 along the first direction, and the first direction is perpendicular to the rotation direction of the first connection component 100.

Of the two opposite ends of the first body 600, one end is connected to the first connection component 100 in the connection device, and this end is called the connection end; the other end is not connected to the first connection component 100, and this end is called the free end. Similarly, of the two opposite ends of the second body 700, one end is connected to the second connection component 200 in the connection device, and this end is called the connection end, and the other end is called the free end.

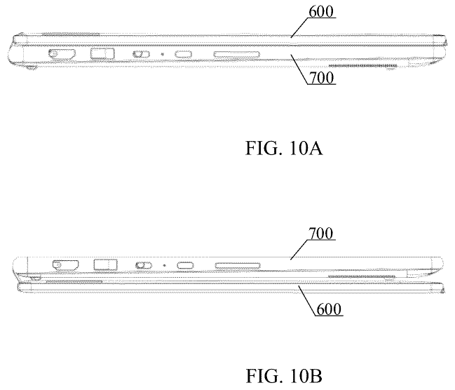

In certain embodiments, and in view of FIG. 10A, the first body 600 is in a first position relative to the second body 700, and the free end of the first body 600 is flush with the free end of the second body 700. The first position may be a relative position of the electronic apparatus in a closed state. For example, the first position may indicate that the unfolding angle between the first body 600 and the second body 700 is 0 degrees.

In certain embodiments, and in view of FIG. 10B, the first body 600 is in a second position relative to the second body 700, the free end of the first body 600 is flush with the free end of the second body 700, and the second position may be the relative position of the electronic apparatus in the unfolded state. For example, the second position may indicate that the unfolding angle between the first body 600 and the second body 700 is 360 degrees.

In certain embodiments, the connection device includes a first connection component 100 and a second connection component 200. The first connection component 100 may include a first rotation shaft 110 and a first rotation shaft connection portion 120. The first rotation shaft connection portion 120 may be fixedly connected to the first body 600 by a mechanical structure such as a bolt. The second connection component 200 may include a second rotation shaft 210 and a second rotation shaft connection portion 220. The second rotation shaft connection portion 220 may be fixedly connected to the second body 700 by a mechanical structure such as bolts.

The end of the first rotation shaft connection portion 120 away from the first rotation shaft 110 is called the first end, the end of the second rotation shaft connection portion 220 away from the second rotation shaft 210 is called the second end, and the distance between the first end and the second end in the first direction is called the connection portion step difference. In certain embodiments, and when the first body 600 is at the first position and the second position relative to the second body 700, the connection portion step difference between the first rotation shaft connection portion 120 and the second rotation shaft connection portion 220 is the same. For example, in the first position, the connection portion step difference is 1 cm (centimeter), and in the second position, the connection portion step difference is also 1 cm. By making the connection portion step difference of the first rotation shaft connection portion 120 and the second rotation shaft connection portion 220 the same at two positions (for example, the first position and the second position), it is ensured that the first body 600 and the second body 700 are flush with each other at the two positions.

In certain embodiments, the first body 600 has a display surface for display and a first surface away from the display surface, and the second body 700 has an input surface for input and a second surface away from the input surface. The direction parallel to the rotation direction of the first connection component 100 is called the second direction.

In the first position, the display surface and the input surface are arranged opposite to each other, and in the projection along the second direction, a line formed by the connection end of the first body 600 and the connection end of the second body 700 has a first tilt angle relative to the first body 600.

In the second position, the first surface and the second surface are arranged opposite to each other, and in the projection along the second direction, a line formed by the connection end of the first body 600 and the connection end of the second body 700 has a second tilt angle relative to the first body 600. In certain particular embodiments, the first tilt angle is equal to the second tilt angle.

In certain embodiments, the first tilt angle is equal to the second tilt angle, so that when the first body 600 is in the first position and the second position relative to the second body 700, the free end of the first body 600 remains flush with the free end of the second body 700, thereby improving the user experience.

The features described in the various embodiments and/or claims of the present disclosure may be combined and/or combined in a variety of ways, even if such combinations and/or combinations are not explicitly described in the present disclosure. In particular, the features described in the various embodiments and/or claims of the present disclosure may be combined and/or combined in a variety of ways without departing from the spirit and teachings of the present disclosure. All of these combinations and/or combinations fall within the scope of the present disclosure.

The embodiments of the present disclosure are described above. However, these embodiments are only for the purpose of illustration and are not intended to limit the scope of the present disclosure. Although the embodiments are described above separately, certain features of the various embodiments may be advantageously used in combination. The scope of the present disclosure is defined by the attached claims and their equivalents. Without departing from the scope of the present disclosure, various substitutions and modifications may be made, which should all fall within the scope of the present disclosure.

What is claimed is:

1. A connection device, comprising:
a first connection component, configured to connect a first body;
a second connection component, configured to connect a second body; and
an adjustment component, configured to connect the first connection component and the second connection component, and to enable rotation of the first connection component with respect to the second connection component,
wherein during a first rotation process, the first connection component and the second connection component rotate synchronously through the adjustment component, and
wherein during a second rotation process, the adjustment component is controlled to enable rotation for one of the first connection component and the second connection component.

2. The connection device of claim 1, wherein the adjustment component includes:
a first linkage member, configured to connect the first connection component and rotate synchronously with the first connection component;
a second linkage member, configured to connect the second connection component and rotate synchronously with the second connection component, wherein the second linkage member includes a first connection portion and a second connection portion, the first connection portion being used for transmission connection with the first linkage member during the first rotation process, and the second connection portion being used for transmission separation between the first linkage member and the second linkage member during the second rotation process; and
a control member, configured to limit the rotation of the first linkage member during the second rotation process.

3. The connection device of claim 2, wherein the control member includes:
a first control member, configured to connect the first connection component and being arranged coaxially with the first linkage member;
a second control member, configured to connect the second connection component and being arranged coaxially with the second linkage member; and
a sliding member, arranged between the first control member and the second control member, and used for switching between the first connection component and the second connection component, so that one of the first connection component and the second connection component enables rotation during the second rotation process.

4. The connection device of claim 3, wherein the first control member is a first wheel body, the second control member is a second wheel body, the sliding member is a slider, and the slider has a first end and a second end,
wherein during the first rotation process, the first end of the slider is in sliding cooperation with the first wheel body, and the second end of the slider is in sliding cooperation with the second wheel body, and
wherein during the second rotation process, the first end of the slider is connected with the first wheel body to limit the rotation of the first wheel body, and the second end of the slider is in sliding cooperation with the second wheel body.

5. The connection device of claim 4,
wherein a side wall of an outer periphery of the first wheel body includes an arc-shaped curved surface and a concave surface concave relative to the arc-shaped curved surface,
wherein a side wall of an outer periphery of the second wheel body includes a first arc surface and a second arc surface, and a radius of the first arc surface is smaller than a radius of the second arc surface,
wherein during the first rotation process, the first end of the slider slides with the arc-shaped curved surface of the first wheel body, and the second end of the slider slides with the first arc surface, and
wherein during the second rotation process, the second arc surface abuts and slides with the second end of the slider, and the first end of the slider abuts with the concave surface of the first wheel body to limit the rotation of the first wheel body.

6. The connection device of claim 4,
wherein an outer side wall of the first wheel body is formed with a first limiting structure and a second limiting structure, the first limiting structure is in a strip shape and extends along a circumference of the first wheel body, and the second limiting structure is in a strip shape and extends along an axial direction of the first wheel body,
wherein an outer side wall of the second wheel body is formed with a third limiting structure and a fourth limiting structure, the third limiting structure is in a strip shape and extends along a circumference of the second wheel body, and the fourth limiting structure is in a spiral shape,
wherein in the first rotation process, the first end of the slider slides with the first limiting structure of the first wheel body, and the second end of the slider slides with the third limiting structure of the second wheel body, and
wherein in the second rotation process, the first end of the slider slides with the second limiting structure of the first wheel body, and the second end of the slider slides with the fourth limiting structure of the second wheel body.

7. The connection device of claim 2,
wherein the first linkage member is a first gear, and the second linkage member is a second gear, the second gear includes an annular side wall, and
wherein the first connection portion is a plurality of gear teeth arranged on the annular side wall and is in transmission connection to the first gear, the second connection portion is an avoidance surface formed by a surface of the annular side wall where no gear teeth are arranged, and the first linkage member and the second linkage member have opposite rotation directions.

8. An electronic apparatus, comprising: a first body, a second body, and a connection device, wherein the connection device includes:
a first connection component, configured to connect a first body;
a second connection component, configured to connect a second body; and
an adjustment component, configured to connect the first connection component and the second connection component, and to enable rotation of the first connection component with respect to the second connection component,
wherein during a first rotation process, the first connection component and the second connection component rotate synchronously through the adjustment component, and
wherein during a second rotation process, the adjustment component is controlled to enable rotation for one of the first connection component and the second connection component.

9. The electronic apparatus of claim 8, wherein the first body is in a first position and a second position relative to the second body, and a free end of the first body is flush with a free end of the second body, and wherein a size of the first body along a first direction is smaller than a size of the second body along the first direction, and the first direction is perpendicular to a rotation direction of the first connection component.

10. The electronic device of claim 8,
wherein the first body has a display surface for display and a first surface facing away from the display surface, and the second body has an input surface for input and a second surface facing away from the input surface,
wherein in a first position, the display surface is arranged opposite to the input surface, and in a projection along a second direction, a connection line formed by a connection end of the first body and a connection end of the second body has a first tilt angle relative to the first body, wherein in a second position, the first surface is arranged opposite to the second surface, and in a projection along the second direction, the connection line formed by the connection end of the first body and the connection end of the second body has a second tilt angle relative to the first body, and
wherein, the second direction is parallel to a rotation direction of the first connection component, and the first tilt angle is equal to the second tilt angle.

11. A connection device, comprising:
a first connection component;
a second connection component; and
an adjustment component, configured to connect the first connection component and the second connection component,
wherein during a first rotation process, the first connection component and the second connection component both rotate through the adjustment component, and
wherein during a second rotation process, the adjustment component is controlled to enable only one but not both of the first connection component and the second connection component to rotate.

12. The connection device of claim 11, wherein the adjustment component includes:
a first linkage member, configured to connect the first connection component;
a second linkage member, configured to connect the second connection component; and
a control member, configured to limit the rotation of the first linkage member during the second rotation process.

13. The connection device of claim 12, wherein the second linkage member includes a first connection portion and a second connection portion, the first connection portion being used for transmission connection with the first linkage member during the first rotation process, and the second connection portion being used for transmission separation between the first linkage member and the second linkage member during the second rotation process.

14. The connection device of claim 13, wherein the control member includes:
a first control member, configured to connect the first connection component and;
a second control member, configured to connect the second connection component; and
a sliding member, arranged between the first control member and the second control member, and used for switching between the first connection component and the second connection component.

15. The connection device of claim 14, wherein the first control member is a first wheel body, the second control member is a second wheel body, the sliding member is a slider.

16. The connection device of claim 15, wherein the slider has a first end and a second end,
wherein during the first rotation process, the first end of the slider is in sliding cooperation with the first wheel body, and the second end of the slider is in sliding cooperation with the second wheel body, and
wherein during the second rotation process, the first end of the slider is connected with the first wheel body to limit the rotation of the first wheel body, and the second end of the slider is in sliding cooperation with the second wheel body.

17. The connection device of claim 15, wherein a side wall of an outer periphery of the first wheel body includes an arc-shaped curved surface and a concave surface concave relative to the arc-shaped curved surface.

18. The connection device of claim 15, wherein a side wall of an outer periphery of the second wheel body includes a first arc surface and a second arc surface, and a radius of the first arc surface is smaller than a radius of the second arc surface.

19. The connection device of claim 15, wherein an outer side wall of the first wheel body is formed with a first limiting structure and a second limiting structure, the first limiting structure extends along a circumference of the first wheel body, and the second limiting structure extends along an axial direction of the first wheel body.

20. The connection device of claim 15, wherein an outer side wall of the second wheel body is formed with a third limiting structure and a fourth limiting structure, the third limiting structure extends along a circumference of the second wheel body, and the fourth limiting structure is in a spiral shape.
